(19) United States
(12) Patent Application Publication
(10) Pub. No.: US 2024/0194540 A1
(43) Pub. Date: Jun. 13, 2024

(54) TWO STEP IMPLANT TO IMPROVE LINE EDGE ROUGHNESS AND LINE WIDTH ROUGHNESS

(71) Applicant: Applied Materials, Inc., Santa Clara, CA (US)

(72) Inventors: John Hautala, Beverly, MA (US); Huixiong Dai, San Jose, CA (US)

(21) Appl. No.: 18/077,809

(22) Filed: Dec. 8, 2022

(51) Int. Cl. H01L 21/66; H01L 21/027; H01L 21/768

(52) U.S. Cl. CPC H01L 22/26; H01L 21/0274; H01L 21/76816; H01L 22/12

(57) ABSTRACT

Methods of processing patterned photoresist to reduce line edge roughness and line width roughness on a semiconductor workpiece are disclosed. The method is performed after the photoresist has been patterned and before the etching process is commenced. Two implants, using different species, are performed at high tilt angles. In certain embodiments, the tilt angle may be 45° or more. Further, the implants are performed at twist angles such that the trajectory of the ions is nearly parallel to the patterned photoresist lines. In this way, the ions from the two implants glance the top and sidewalls of the photoresist lines. Using this technique, the LER and LWR of the photoresist lines may be reduced with minimal impact on the CD.

Embodiments of the present disclosure relate to a method of improving line edge roughness and line width roughness of photoresist features using multiple implants.

### BACKGROUND

As semiconductor fabrication processes continue to evolve, line widths are become increasingly smaller. One effect of this is an increase in line width roughness (LWR) and line edge roughness (LER). Line width roughness is a measure of the variation of the width of a feature on the semiconductor workpiece. Line edge roughness may be defined as the three sigma deviation of a line edge from a straight line.

To ensure uniform device performance, these metrics are sought to be as low as possible. Traditional lithography techniques may be used to achieve features having the desired critical dimension (CD). However, these features may have an unacceptable LWR and/or LER measurements. For example, artifacts of pattern transfer, such as line roughness, line wiggling and variations in line width, may occur. This variation leads to performance variation, and possibly yield degradation.

Various processes have been proposed and attempted to reduce LER and LWR without affecting CD, with limited success.

Therefore, it would be beneficial if there were a method of processing the patterned photoresist on a workpiece so as to reduce LER and LWR while having minimal impact on the critical dimension.

### SUMMARY

Methods of processing patterned photoresist to reduce line edge roughness and line width roughness on a semiconductor workpiece are disclosed. The method is performed after the photoresist has been patterned and before the etching process is commenced. Two implants, using different species, are performed at high tilt angles. In certain embodiments, the tilt angle may be 45° or more. Further, the implants are performed at twist angles such that the trajectory of the ions is nearly parallel to the patterned photoresist lines. In this way, the ions from the two implants glance the top and sidewalls of the photoresist lines. Using this technique, the LER and LWR of the photoresist lines may be reduced with minimal impact on the CD.

According to one embodiment, a method of reducing line edge roughness (LER) and line width roughness (LWR) of a patterned photoresist disposed on a workpiece is disclosed. The patterned photoresist has sidewalls and a thickness known as a critical dimension (CD), and the workpiece is disposed on a platen capable of twist about a rotational axis and tilt about a tilt axis. The method comprises orienting the workpiece on the platen by selecting a twist angle of the platen so as to align a trajectory of an incoming ion beam to a primary photoresist direction and by selecting a high tilt angle, wherein the primary photoresist direction is parallel to the sidewalls; directing a first ion beam having a first species toward the workpiece after the orienting; and directing a second ion beam having a second species, different from the first species, toward the workpiece after directing the first ion beam while the workpiece remains oriented. In some embodiments, an implant energy and a dose of the first species and an implant energy and a dose of the second species are selected so that LER and LWR are reduced by at least 10% and the critical dimension of the patterned photoresist is affected by less than 1 nm. In certain embodiments, the first species comprises silicon. In some embodiments, second species comprises an inert species. In certain embodiments, the inert species comprises argon. In certain embodiments, the second species comprises oxygen or nitrogen. In some embodiments, the patterned photoresist comprises a plurality of photoresist lines and the high tilt angle is at least 45°. In certain embodiments, the high tilt angle is between 60° and 80°. In certain embodiments, orienting the workpiece comprises selecting a twist angle such that an angle between the primary photoresist direction and the trajectory of the incoming ion beam less than 5°.

According to another embodiment, a method of reducing line edge roughness (LER) and line width roughness (LWR) of a patterned photoresist disposed on a workpiece is disclosed. The patterned photoresist has sidewalls and a thickness known as a critical dimension (CD), and the workpiece is disposed on a platen capable of twist about a rotational axis and tilt about a tilt axis. The method comprises orienting the workpiece on the platen by selecting a twist angle of the platen so as to align a primary photoresist direction to a trajectory of an incoming ion beam and by selecting a high tilt angle, wherein the primary photoresist direction is parallel to the sidewalls; directing a first ion beam comprising silicon ions toward the workpiece after the orienting; rotating the workpiece 180° after directing the first ion beam; directing the first ion beam toward the workpiece a second time after rotating; directing a second ion beam having a second species, different from the silicon ions, toward the workpiece; rotating the workpiece 180° after directing the second ion beam; and directing the second ion beam toward the workpiece a second time after rotating a second time. In some embodiments, an implant energy and a dose of the silicon ions and an implant energy and a dose of the second species are selected so that LER and LWR are reduced by at least 10% and the critical dimension of the patterned photoresist is affected by less than 1 nm. In some embodiments, second species comprises an inert species. In certain embodiments, the inert species comprises argon. In certain embodiments, the second species comprises oxygen or nitrogen. In some embodiments, the patterned photoresist comprises a plurality of photoresist lines and the high tilt angle is at least 45°. In certain embodiments, the high tilt angle is between 60° and 80°. In certain embodiments, orienting the workpiece comprises selecting a twist angle such that an angle between the primary photoresist direction and the trajectory of the incoming ion beam less than 5°.

According to another embodiment, a method of reducing line edge roughness (LER) and line width roughness (LWR) of a patterned photoresist disposed on a workpiece is disclosed. The patterned photoresist has sidewalls and a thickness known as a critical dimension (CD), and the workpiece is disposed on a platen capable of twist about a rotational axis and tilt about a tilt axis. The method comprises orienting the workpiece on the platen by selecting a twist angle of the platen so as to align a trajectory of an incoming ion beam to a primary photoresist direction and by selecting a high tilt angle, wherein the primary photoresist direction is parallel to the sidewalls; and directing an ion beam having an inert species toward the workpiece while the workpiece remains oriented. In certain embodiments, orienting the workpiece comprises selecting a twist angle such that an angle between the primary photoresist direction and the trajectory of the incoming ion beam less than 5° and selecting a high tilt angle of at least 45°. In some embodiments, an implant energy and a dose of the inert species are selected so that LER and LWR are reduced by at least 10% and the critical dimension of the patterned photoresist is affected by less than 1 nm.

### BRIEF DESCRIPTION OF THE FIGURES

For a better understanding of the present disclosure, reference is made to the accompanying drawings, which are incorporated herein by reference and in which:

FIGS. 1A-1B show different photoresist patterns on a workpiece;

FIG. 2A-2C shows the rotation and tilt of a workpiece on the platen;

FIG. 3 is an ion implantation system in accordance with one embodiment that may be used to perform the processes described herein; and

FIG. 4 shows a sequence to reduce LER and LWR of a photoresist feature.

### DETAILED DESCRIPTION

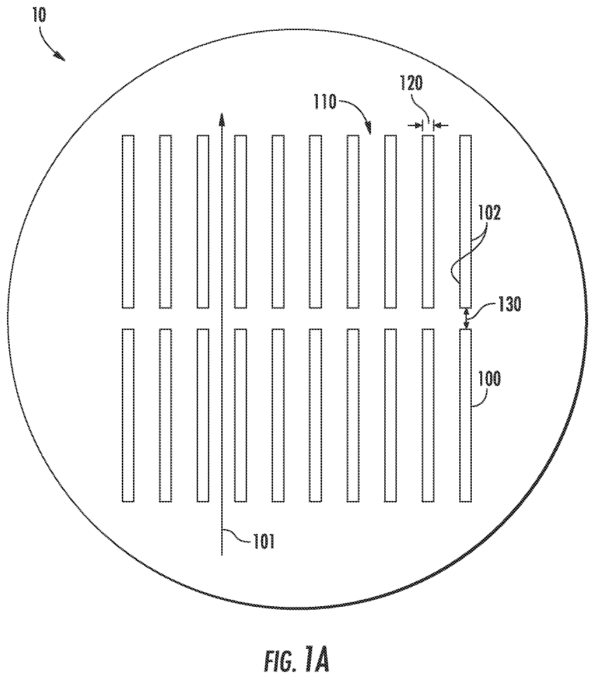

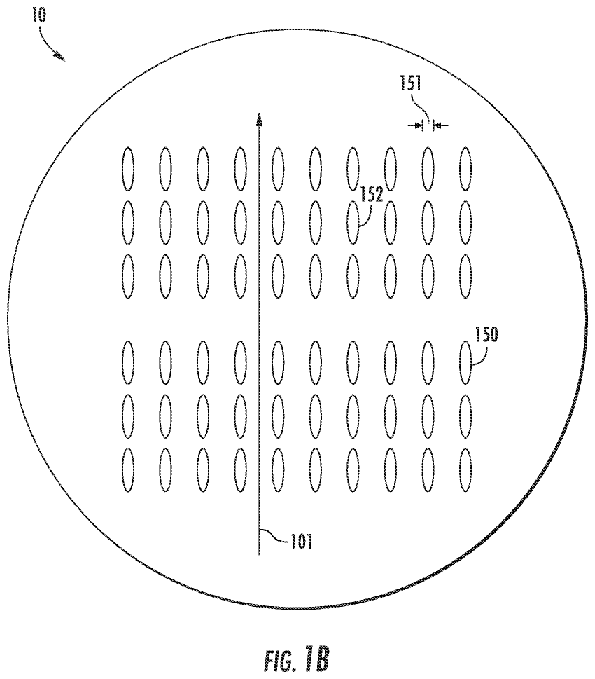

FIG. 1A shows a workpiece 10 with a patterned photoresist according to one embodiment. In this embodiment, the patterned photoresist is disposed in photoresist lines 100, such that trenches 110 are formed between adjacent photoresist lines 100. The thickness of the photoresist lines 100, defined as a distance between the two parallel sidewalls 102 of the line, is referred to as the critical dimension (CD) 120. The distance between two photoresist lines 100 disposed in the same column is referred to as tip-to-tip distance 130. The photoresist lines 100 have a long dimension, which corresponds to the sidewalls 102, and a width (or CD). The direction parallel to the sidewalls 102 of the photoresist line 100 may be referred to as the primary photoresist direction 101 in this disclosure.

FIG. 1B shows a workpiece 10 with a patterned photoresist according to another embodiment. In this embodiment, the patterned photoresist is disposed so as to create photoresist recesses 150, wherein the photoresist covers the rest of the workpiece 10 except the photoresist recesses 150. Thus, while FIG. 1A shows where the regions where the photoresist is present, FIG. 1B shows the regions where the photoresist is absent. The critical dimension 151 of the photoresist recess 150 is defined as the width of the photoresist recess 150. The direction parallel to the long dimension, which corresponds to the sidewalls 152, of the photoresist recess 150 may be referred to as the primary photoresist direction 101 in this disclosure.

As described above, minimizing the LER and LWR of patterned photoresist without negatively impacting CD is an ongoing goal. In some embodiments, it is beneficial to reduce LER and LWR by at least 10%. In other embodiments, it is beneficial to reduce LER and LWR by at least 158. However, typically, a reduction in LER and LWR also results in a change in CD 120. The present disclosure described techniques to reduce LER and LWR with minimal affect (<1 nm) on CD 120.

The photoresist may be a CAR (chemically amplified resist) photoresist or another suitable material.

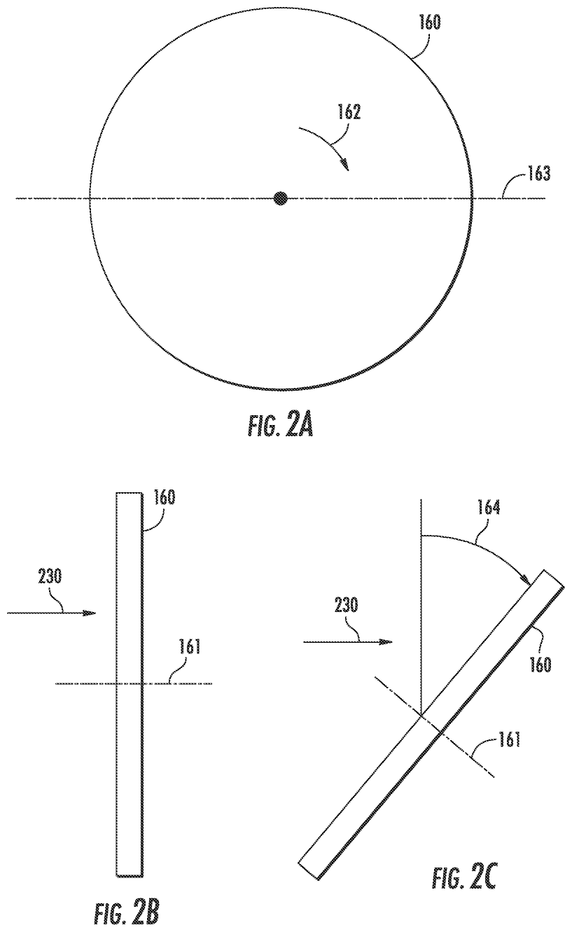

FIG. 2A shows a front view of a platen 160 that is capable of rotation, referred to as a roplat. FIG. 2B shows a side view of the platen 160. The platen 160 is able to twist about a rotational axis 161 that includes the center of the platen 160 and is perpendicular to the front surface of the platen 160. Rotation about this rotational axis 161 is referred to a twist angle 162. The platen 160 is also able to rotate about a tilt axis 163 that includes the center of the platen 160 and is parallel to the front surface of the platen. FIG. 2C shows the platen 160 tilted relative to vertical by a tilt angle 164. Note that a tilt angle 164 of 0° indicates that the incoming ion beam 230 is normal to the front surface of the platen 160, while a tilt angle of 90° indicates that the incoming ion beam 230 is parallel to the front surface of the platen 160.

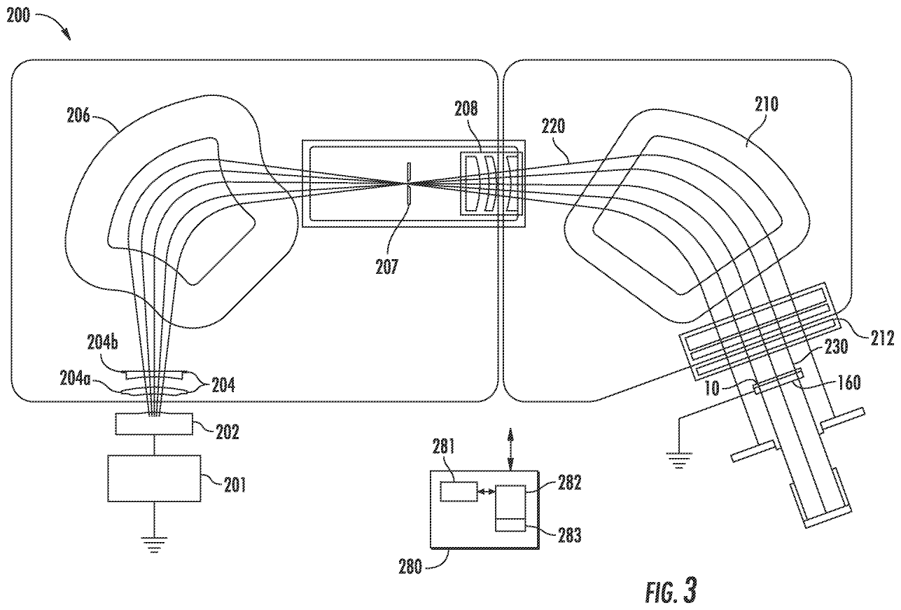

FIG. 3 shows a beamline ion implantation system 200 that utilizes a ribbon ion beam. As illustrated in the figure, the beamline ion implantation system 200 may comprise an ion source and a complex series of beam-line components through which an ion beam 220 passes. The ion source may comprise an ion source chamber 202 where ions are generated. The ion source may also comprise a power source 201 and extraction electrodes 204 disposed near the ion source chamber 202. The extraction electrodes 204 may include a suppression electrode 204a and a ground electrode 204b. Each of the ion source chamber 202, the suppression electrode 204a, and the ground electrode 204b may include an aperture. The ion source chamber 202 may include an extraction aperture (not shown), the suppression electrode 204a may include a suppression electrode aperture (not shown), and a ground electrode 204b may include a ground electrode aperture (not shown). The apertures may be in communication with one another so as to allow the ions generated in the ion source chamber 202 may pass through, toward the beam-line components.

The beamline components may include, for example, a mass analyzer 206, a mass resolving aperture 207, a first acceleration or deceleration (A1 or D1) stage 208, a collimator 210, and a second acceleration or deceleration (A2 or D2) stage 212. Much like a series of optical lenses that manipulate a light beam, the beamline components can filter, focus, and manipulate ions or ion beam 220. The ion beam 220 that passes through the beamline components may be directed toward the workpiece 10 that is mounted on a platen 160. The incoming ion beam 230 is much wider in the first direction than in the second direction and may be wider than the diameter of the workpiece 10 in the first direction. The direction of travel for the incoming ion beam 230, which is perpendicular to the first direction and the second direction, may be referred to as its trajectory. The workpiece 10 may be moved in one or more dimensions by the platen 160. For example, the platen 160 may move in the second direction (which corresponds to the height of the incoming ion beam 230) so that, after the platen 160 has moved from its first position to its second position, the entire workpiece 10 is exposed to the incoming ion beam 230. The platen 160 may be configured to rotate the workpiece 10 about the rotational axis 161 and tilt axis 163 (see FIGS. 2A-2C).

A controller 280 is also used to control the implantation. The controller 280 has a processing unit 281 and an associated memory device 282. This memory device 282 contains the instructions 283, which, when executed by the processing unit 281, enable the system to perform the functions described herein. The controller 280 is able to control the twist angle 162 and tilt angle 164 of the platen 160. This memory device 282 may be any non-transitory storage medium, including a non-volatile memory, such as a FLASH ROM, an electrically erasable ROM or other suitable devices. In other embodiments, the memory device 282 may be a volatile memory, such as a RAM or DRAM. In certain embodiments, the controller 280 may be a general purpose computer, an embedded processor, or a specially designed microcontroller. The actual implementation of the controller 280 is not limited by this disclosure.

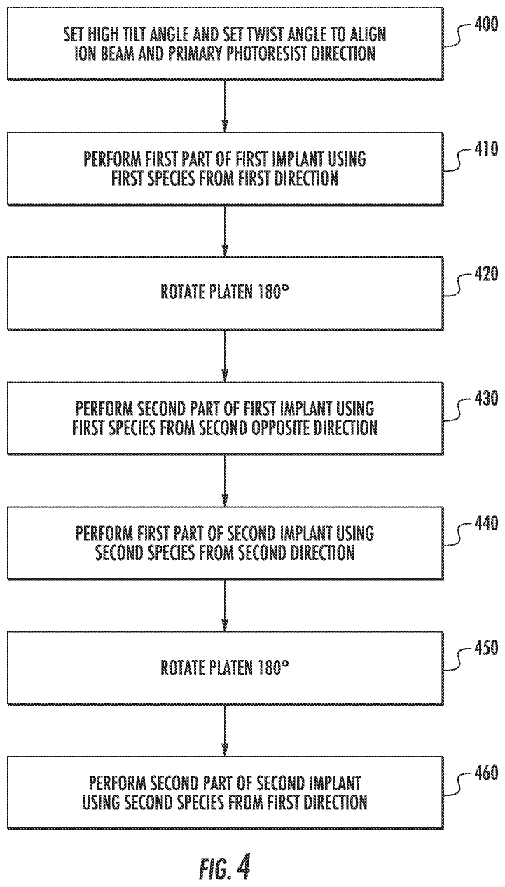

FIG. 4 shows a sequence of processes that may be performed to decrease the LER and LWR of a photoresist line or photoresist recess while minimally impacting the CD. This sequence may be advantageous when CAR is used as the photoresist material, for example. First, as shown in Box 400, the platen 160 is oriented for the first implant. The platen 160 is set to a tilt angle 164, which may be a high tilt angle. In the case of photoresist lines 100, as shown in FIG. 1A, a high tilt angle is defined as an angle that is at least 45°. In some embodiments, the tilt angle may be 60° or greater. The tilt angle may be as large as 80°. In the case of a photoresist recess 150, as shown in FIG. 1B, a high tilt angle may be defined as an angle between 20° and 30°. Further, the twist angle 162 is set such that the trajectory of the incoming ion beam 230 is aligned with the primary photoresist direction 101. In some embodiments, the twist angle is selected so that the trajectory of the incoming ion beam 230 and the primary photoresist direction 101 are parallel. In some embodiments, the difference between the trajectory of the incoming ion beam 230 and the primary photoresist direction 101 may be 5° or less. In certain embodiments, the difference may be 3° or less. In some embodiments, the difference may be 1° or less.

Once the platen 160 is properly positioned, the first part of the first implant may be performed, as shown in Box 410. The first implant is an implant of a first species, which may comprise silicon ions.

After the first portion of the total dose is implanted, the platen 160 may be rotated 180°, as shown in Box 420. In this way, the angle between the primary photoresist direction 101 and the trajectory of the incoming ion beam 230 is the same as it was during the implant done in Box 410. The tilt angle is not changed at this time. In other words, after rotation, the difference between the trajectory of the incoming ion beam 230 and the primary photoresist direction 101 may be 5° or less. In certain embodiments, the difference may be 3° or less. In some embodiments, the difference may be 1° or less. Thus, in this disclosure, although the twist angle is denoted as 180°, it is understood that the twist angle may vary slightly from this value as long as, after rotation, the difference between the trajectory of the incoming ion beam 230 and the primary photoresist direction 101 is still within the desired range. The second part of the first implant is then performed from the opposite direction, as shown in Box 430. The total dose of the first species applied during the first part and the second part may be between 1E14 ions/cm² and 1E17 ions/cm². In some embodiments, the total dose may be between 1E15 ions/cm² and 8E15 ions/cm². The energy of the first implant may be between 400 eV and 2 keV.

Note that in some embodiments, Boxes 420-430 may be omitted. In this case, all of the dose is provided during the first part of the first implant.

After the first implant is complete, a second implant, using a second species, is performed. The tilt angle and twist angle are as described above. The second species may be argon, although other species may be used. In some embodiments, the second species may include other inert species, such as neon, radon, krypton or xenon. In other embodiments, the second species may include oxygen or nitrogen. The second implant may be performed using the same energy as the first implant. The first part of the second implant is then performed, as shown in Box 440.

After the first part of the second implant is completed, the platen 160 may then be rotated 180°, as shown in Box 450. The second part of the second implant may then be performed from the opposite direction as shown in Box 460. The total dose of the second species applied during the first part and the second part of the second implant may be between 1E14 ions/cm² and 1E17 ions/cm². In some embodiments, the total dose may be between 1E15 ions/cm² and 2E16 ions/cm². In some embodiments, the total dose is at least 4E15 ions/cm².

Note that in some embodiments, Boxes 450-460 may be omitted. In this case, all of the dose is provided during the first part of the second implant.

The sequence shown in FIG. 4 may be modified. For example, the workpiece may be rotated before the first part of the second implant (i.e., before Box 440). In this way, the first part of both implants is from the same direction.

The use of two implants provides benefits that are not possible using only one implant. Specifically, using certain photoresist materials, such as CAR, argon alone may reduce LER and LWR, but also significantly reduces the CD. For example, using dose of 1E15 ions/cm² or more, argon reduces CD by more than 1 nm. Without being bound to any particular theory, it is believed that the first implant adds structural support to the photoresist, making it more resistant to the sputtering effect of the second implant.

It has also been found that the sequence shown in FIG. 4 may be abridged for certain photoresist materials. For example, when a metal oxide, such as SnOx, is used as the photoresist material, many of the benefits described above may be achieved by performing only the second implant. In other words, by orienting the trajectory of the incoming ion beam 230 with the primary photoresist direction 101, as described above, an implant of the second species, which may be an inert species, oxygen or nitrogen, may achieve a reduction in LER and LWR of at least 10% with minimal impact to CD (i.e., <1 nm). Thus, for metal oxide photoresists, the sequence shown in FIG. 4 may be modified by eliminating Boxes 410-430.

The embodiments described above in the present application may have many advantages. The sequence shown in FIG. 4 may be used to significantly reduce LER and LWR with minimal impact on CD. In one test, using silicon as the first species and argon as the second species, a reduction in LER and LWR of greater than 10% was achieved, while the reduction in CD was less than 1 nm. In some tests, the reduction in LER and LWR was greater than 15%, while the reduction in CD was less than 1 nm. These tests were performed using tilt angles of between 60° and 80° and energies of between 0.7 keV and 1.0 keV. The total dose of the first species is between 1E15 and 4E15 ions/cm² while the total dose of the second species is between 2E15 and 2E16 ions/cm².

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A method of reducing line edge roughness (LER) and line width roughness (LWR) of a patterned photoresist disposed on a workpiece, wherein the patterned photoresist has sidewalls and a thickness known as a critical dimension (CD), and wherein the workpiece is disposed on a platen capable of twist about a rotational axis and tilt about a tilt axis, the method comprising:
orienting the workpiece on the platen by selecting a twist angle of the platen so as to align a trajectory of an incoming ion beam to a primary photoresist direction and by selecting a high tilt angle, wherein the primary photoresist direction is parallel to the sidewalls;
directing a first ion beam having a first species toward the workpiece after the orienting; and
directing a second ion beam having a second species, different from the first species, toward the workpiece after directing the first ion beam while the workpiece remains oriented.

2. The method of claim 1, wherein an implant energy and a dose of the first species and an implant energy and a dose of the second species are selected so that LER and LWR are reduced by at least 10% and the critical dimension of the patterned photoresist is affected by less than 1 nm.

3. The method of claim 1, wherein the first species comprises silicon.

4. The method of claim 1, wherein the second species comprises an inert species.

5. The method of claim 4, wherein the inert species comprises argon.

6. The method of claim 1, wherein the second species comprises oxygen or nitrogen.

7. The method of claim 1, wherein the patterned photoresist comprises a plurality of photoresist lines and the high tilt angle is at least 45°.

8. The method of claim 7, wherein the high tilt angle is between 60° and 80°.

9. The method of claim 1, wherein orienting the workpiece comprises selecting a twist angle such that an angle between the primary photoresist direction and the trajectory of the incoming ion beam less than 5°.

10. A method of reducing line edge roughness (LER) and line width roughness (LWR) of a patterned photoresist disposed on a workpiece, wherein the patterned photoresist has sidewalls and a thickness known as a critical dimension (CD), and wherein the workpiece is disposed on a platen capable of twist about a rotational axis and tilt about a tilt axis, the method comprising:
orienting the workpiece on the platen by selecting a twist angle of the platen so as to align a primary photoresist direction to a trajectory of an incoming ion beam and by selecting a high tilt angle, wherein the primary photoresist direction is parallel to the sidewalls;
directing a first ion beam comprising silicon ions toward the workpiece after the orienting;
rotating the workpiece 180° after directing the first ion beam;
directing the first ion beam toward the workpiece a second time after rotating;
directing a second ion beam having a second species, different from the silicon ions, toward the workpiece;
rotating the workpiece 180° after directing the second ion beam; and
directing the second ion beam toward the workpiece a second time after rotating a second time.

11. The method of claim 10, wherein an implant energy and a dose of the silicon ions and an implant energy and a dose of the second species are selected so that LER and LWR are reduced by at least 10% and the critical dimension of the patterned photoresist is affected by less than 1 nm.

12. The method of claim 10, wherein the second species comprises an inert species.

13. The method of claim 12, wherein the inert species comprises argon.

14. The method of claim 10, wherein the second species comprises oxygen or nitrogen.

15. The method of claim 10, wherein the patterned photoresist comprises a plurality of photoresist lines and the high tilt angle is at least 45°.

16. The method of claim 15, wherein the high tilt angle is between 60° and 80°.

17. The method of claim 10, wherein orienting the workpiece comprises selecting a twist angle such that an angle between the primary photoresist direction and the trajectory of the incoming ion beam less than 5°.

18. A method of reducing line edge roughness (LER) and line width roughness (LWR) of a patterned photoresist disposed on a workpiece, wherein the patterned photoresist has sidewalls and a thickness known as a critical dimension (CD), and wherein the workpiece is disposed on a platen capable of twist about a rotational axis and tilt about a tilt axis, the method comprising:
orienting the workpiece on the platen by selecting a twist angle of the platen so as to align a trajectory of an incoming ion beam to a primary photoresist direction and by selecting a high tilt angle, wherein the primary photoresist direction is parallel to the sidewalls; and
directing an ion beam having an inert species toward the workpiece while the workpiece remains oriented.

19. The method of claim 18, wherein orienting the workpiece comprises selecting a twist angle such that an angle between the primary photoresist direction and the trajectory of the incoming ion beam less than 5° and selecting a high tilt angle of at least 45°.

20. The method of claim 18, wherein an implant energy and a dose of the inert species are selected so that LER and LWR are reduced by at least 10% and the critical dimension of the patterned photoresist is affected by less than 1 nm.
